(19) United States
(12) Patent Application Publication
(10) Pub. No.: US 2026/0111629 A1
(43) Pub. Date: Apr. 23, 2026

(54) METHOD AND SYSTEM FOR ESTIMATING CARBON FIXATION

(71) Applicant: Phytech Ltd., Kfar Saba (IL)

(72) Inventors: Ido GARDI, Kibbutz Kfar Hahoresh (IL); Omer GUY, Doar-Na Emek Beit SheAn (IL); Sarig DUEK, Doar-Na Tzafon Yehuda (IL)

(73) Assignee: Phytech Ltd., Kfar Saba (IL)

(21) Appl. No.: 19/476,194

(22) PCT Filed: Apr. 17, 2024
(86) PCT No.: PCT/IL2024/050382

§ 371 Date: Oct. 17, 2025

Related U.S. Application Data
(60) Provisional application No. 63/460,342, filed on Apr. 19, 2023.

(51) Int. Cl. G06F 30/20

(52) U.S. Cl. CPC G06F 30/20

(57) ABSTRACT

A method of estimating amount of carbon fixation in a plant comprises receiving a set of temporal sequences, respectively corresponding to a set of consecutive days, each sequence describing a size of a part of the plant as measured repeatedly over one of the days. Morphologically equivalent pairs of sequences are identified in the set of sequences, and parameter subtraction is applied between parameters representing sequences in each pair of at least a portion of the pairs, to provide a size change of the plant part for the pair. The method estimates the amount of carbon fixation in the plant based on the size change.

### RELATED APPLICATION

This application claims the benefit of priority of U.S. Provisional Patent Application No. 63/460,342, filed on Apr. 19, 2023, the contents of which are incorporated herein by reference in their entirety.

### FIELD AND BACKGROUND OF THE INVENTION

The present invention, in some embodiments thereof, relates to agriculture and, more particularly, but not exclusively, to a method and system for estimating carbon fixation in plants.

Photosynthesis is a chain of reactions which assimilate inorganic carbon (in the form of carbon dioxide) to organic carbon (in the form of carbohydrate). Estimation of carbon fixation in plants is useful for understanding the role of photosynthetic organisms in the carbon cycle, and for optimizing agricultural processes. Estimation of carbon fixation is also useful in green economy, particularly is the trade in carbon gas, whereby carbon emissions and offsets are traded under carbon trading mechanisms. A carbon trading mechanism is a legal trading scheme or standard that acknowledges certain activities as a carbon credit. One sector in carbon trading is developing carbon offsets from terrestrial carbon sequestration and storage. Carbon is sequestered and stored by plants and/or vegetation. Under certain carbon trading mechanisms, the carbon that is sequestered and stored in plants or vegetation can be monetized as an offset through credible anthropogenic activities.

The stored carbon in plants can be divided into residence-time based groups representing the time for the carbon to release back from the plant to the atmosphere. Short time residence carbon can be consumed by cell respiration and to be released within hours and can be up 10% of the plant production [Randerson, J. T., Chapin, F. S. I., Harden, J. W., Neff, J. C., Harmon, M. E., (2002): Net ecosystem production: a comprehensive measure of net carbon. accumulation by ecosystems. Ecol. Appl. 12, 937-947]. Intermediate residence carbon stored in plant organs such as root hears, leaves, flowers, and fruit with storing time of several month. Long term residence carbon stored in the woody organs of a tree. Utilized carbon makes up to 50% of the dry biomass of a tree, therefore grater increase in tree biomass is the inevitable result of higher carbon sequestration.

### SUMMARY OF THE INVENTION

According to an aspect of some embodiments of the invention there is provided a method of estimating amount of carbon fixation in a plant. The method comprises: receiving a set of temporal sequences, respectively corresponding to a set of consecutive days, each sequence describing a size of a part of the plant as measured repeatedly over one of the days. The method also comprises identifying morphologically equivalent pairs of sequences in the set of sequences, and subtracting between parameters representing sequences in each pair of at least a portion of the pairs, to provide a size change of the plant part for the pair. The method further comprises estimating the amount of carbon fixation in the plant based on the size change.

According to some embodiments of the invention the identifying comprises applying a statistical analysis to a distribution of differences between values of respective elements of the sequences of the pair.

According to some embodiments of the invention the statistical analysis comprises a flatness test.

According to some embodiments of the invention the sequences of the pair are identified as being morphologically equivalent when at least 60% of the distribution satisfies the flatness test. According to some embodiments of the invention the pair corresponds to two adjacent days of the set of consecutive days.

According to some embodiments of the invention the parameters comprise a local maximum of each of the sequences in the pair.

According to some embodiments of the invention the method comprises applying smoothing to the parameters prior to the subtraction.

According to some embodiments of the invention the smoothing comprises a moving average.

According to some embodiments of the invention the moving average is a weighted moving average.

According to some embodiments of the invention the method estimates a daily amount.

According to some embodiments of the invention the method estimates an amount of carbon fixated over a period of a plurality of days based on accumulation of size changes over the plurality of days.

According to some embodiments of the invention the method comprises interpolating daily size changes for sequences that fail to be identified as morphologically equivalent.

According to some embodiments of the invention the method comprises applying forward extrapolation to the accumulated size changes over a future time period, and predicting an expected amount of carbon fixation in the future time period.

According to some embodiments of the invention a length of the future time period is less than six months.

According to some embodiments of the invention the method comprises estimating a weight of the plant based on the size, wherein the estimating is based also on the estimated weight.

According to some embodiments of the invention the plant part is a trunk.

According to some embodiments of the invention the plant part is a stem.

According to some embodiments of the invention the plant part is a fruit.

According to some embodiments of the invention the method comprises receiving signals from a sensing element attached to the plant part, and extracting the temporal sequences from the signal.

According to some embodiments of the invention the sensing element comprises a dendrometer.

According to some embodiments of the invention the method comprises applying a statistical procedure to the amount of carbon fixation in the plant to provide an estimate for an amount of carbon fixation in a population of plants.

According to some embodiments of the invention the method comprises establishing a connection to a user account within an emission allowance trading system, and associating a database record pertaining to the estimated amount to the user account.

According to some embodiments of the invention the method comprises operating a crop treatment system responsively to the estimated amount.

According to an aspect of some embodiments of the present invention there is provided a computer software product. The computer software product comprises a non-volatile computer-readable medium in which program instructions are stored, which instructions, when read by a data processor, cause the data processor to receive a set of temporal sequences, respectively corresponding to a set of consecutive days, each sequence describing a size of a part of the plant as measured repeatedly over one of the days, and to execute the method as delineated above and optionally and preferably as further detailed below.

According to an aspect of some embodiments of the present invention there is provided a system for estimating amount of carbon fixation in a plant. The system comprises a communication system configured to receive over a communication network a set of temporal sequences, respectively corresponding to a set of consecutive days, each sequence describing a size of a part of the plant as measured repeatedly over one of the days; and a data processor configured to receive the signal and to execute the method as delineated above and optionally and preferably as further detailed below.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

Implementation of the method and/or system of embodiments of the invention can involve performing or completing selected tasks manually, automatically, or a combination thereof. Moreover, according to actual instrumentation and equipment of embodiments of the method and/or system of the invention, several selected tasks could be implemented by hardware, by software or by firmware or by a combination thereof using an operating system.

For example, hardware for performing selected tasks according to embodiments of the invention could be implemented as a chip or a circuit. As software, selected tasks according to embodiments of the invention could be implemented as a plurality of software instructions being executed by a computer using any suitable operating system. In an exemplary embodiment of the invention, one or more tasks according to exemplary embodiments of method and/or system as described herein are performed by a data processor, such as a computing platform for executing a plurality of instructions. Optionally, the data processor includes a volatile memory for storing instructions and/or data and/or a non-volatile storage, for example, a magnetic hard-disk and/or removable media, for storing instructions and/or data. Optionally, a network connection is provided as well. A display and/or a user input device such as a keyboard or mouse are optionally provided as well.

### BRIEF DESCRIPTION OF THE SEVERAL VIEWS OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 is a flowchart diagram of a method suitable for estimating amount of carbon fixation in a plant according to some embodiments of the present invention;

FIGS. 2A-C are illustrations describing a representative example of an application of a similarity criterion between morphologies of two sequences according to some embodiments of the present invention;

FIG. 3 is a schematic illustration showing a block diagram of a system for estimating amount of carbon fixation in one or more plants, according to some embodiments of the present invention;

FIG. 4 shows a plotted version of a set of 70 sequences corresponding to a set of 70 consecutive days, as extracted from signals received from a sensor attached to a stem of Gala apple tree during experiments performed according to some embodiments of the present invention;

FIGS. 5A and 5B show calculated daily change in carbon content of two gala apple irrigation projects, as obtained during experiments performed according to some embodiments of the present invention; and

FIG. 6 shows estimated carbon stored in two almond trees, as obtained during experiments performed according to some embodiments of the present invention.

### DESCRIPTION OF SPECIFIC EMBODIMENTS OF THE INVENTION

The present invention, in some embodiments thereof, relates to agriculture and, more particularly, but not exclusively, to a method and system for estimating carbon fixation in plants.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

Carbon fixation is the process by which plants convert carbon dioxide from the atmosphere into organic compounds through the process of photosynthesis. During photosynthesis, water molecules are dissociated into oxygen and hydrogen ions. The hydrogen ions are then used as a source of energy to form ATP, and the oxygen is released. Carbon dioxide from the atmosphere is then absorbed by the plant's leaves, enters the chloroplasts, combines, and converted into organic compounds, such as glucose and other sugars. These compounds are then used by the plant for energy, growth, and maintenance.

The present inventors have devised a method and a system that receive data describing the size of a plant part as a function of the time, and utilize the data to estimate an amount of carbon fixation in the plant.

As used herein “plant part” refers to any part of a plant, such as, but not limited to, a trunk, a stem, and a fruit of the plant.

Over the past few decades, trunk diameter has been examined in plants in order to identify water stress. It is recognized that the size of the plant part (e.g., the diameter of the trunk) exhibits variations throughout the day, and that these variations are sensitive to water stress. The inventors found that the sensitivity is due to the significant influence of the water balance on the size of the plant part. The inventors found that much more than 90% sometimes even more than 99% of the variation of the size is due to changes in water balance, e.g., the hydration and dehydration of the bark. Other factors, such as an actual change in the dry matter or a change in the amount of carbon that is stored in the plant, have only a minor contribution (less than 10%) to the variation of the size.

The inventors have therefore realized that it is difficult to relate the variation of the size of the plant part to carbon fixation because the carbon fixation is expressed as changes in the amount of dry matter, and carbon storage or carbon redistribution (carbohydrates, fats, cell division), and the contribution of these factors to the size variation are masked by the much more considerably contribution of the water balance.

In a search for a technique to more accurately estimate the carbon fixation in a plant, the inventors found that it is possible to at least partially diminish the masking by searching for days with similar changes in the water balance, and using this information for estimating the contribution of factors other than water balance to the changes in size in such days.

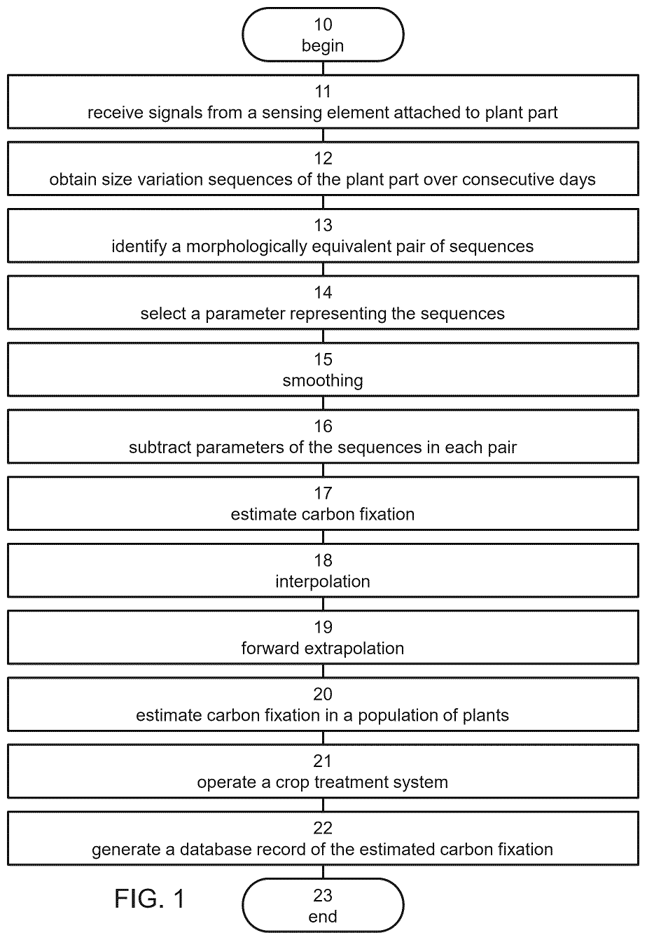

Referring now to the drawings, FIG. 1 is a flowchart diagram of a method suitable for estimating amount of carbon fixation in a plant according to various exemplary embodiments of the present invention. It is to be understood that, unless otherwise defined, the operations described hereinbelow can be executed either contemporaneously or sequentially in many combinations or orders of execution. Specifically, the ordering of the flowchart diagrams is not to be considered as limiting. For example, two or more operations, appearing in the following description or in the flowchart diagrams in a particular order, can be executed in a different order (e.g., a reverse order) or substantially contemporaneously. Additionally, several operations described below are optional and may not be executed.

At least part of the operations described herein can be implemented by a data processing system, e.g., a dedicated circuitry or a general purpose computer, configured for receiving data and executing the operations described below. At least part of the operations can be implemented by a cloud-computing facility at a remote location. One or more of the operations described below can be implemented by a data processor of a mobile device, such as, but not limited to, a smartphone, a tablet, a smartwatch and the like, supplemented by software app programed to receive data and execute processing operations.

Computer programs implementing the method can commonly be distributed to users on a distribution medium such as, but not limited to, a flash memory or a remote medium communicating with a local computer over the internet. From the distribution medium, the computer programs can be copied to a hard disk or a similar intermediate storage medium. The computer programs can be run by loading the computer instructions either from their distribution medium or their intermediate storage medium into the execution memory of the computer, configuring the computer to act in accordance with the method. All these operations are well-known to those skilled in the art of computer systems.

The method can be embodied in many forms. For example, it can be embodied on a tangible medium such as a computer for performing the method steps. It can be embodied on a computer readable medium, comprising computer readable instructions for carrying out the method steps. In can also be embodied in electronic device having digital computer capabilities arranged to run the computer program on the tangible medium or execute the instruction on a computer readable medium.

The method begins at 10 and optionally and preferably continues to 11 at which monitoring signals are received from a sensing element attached to the plant part. The sensing element is configured for measuring changes in the size of the plant part and transmitting signals indicative of the measured size, preferably to a remote location at which further processing is executed as described below. The initial size of the plant part is optionally and preferably known, and so the measured changes, together with the initial size provide information regarding the absolute size of the plant part. Typically, initial size is measured during the installation of the sensing element. In various exemplary embodiments of the invention the sensing element comprises one or more dendrometers.

A dendrometer is a known device, which typically comprises a transducer member which is capable of mechanically flexing in response to changes in plant stem or trunk size. The transducer member can include strain gauges, such as, but not limited to, electronic strain gauges, attached thereto in a configuration which allows flexing of the transducer member to be measured as the level of strain in the attached strain gauges vary.

A dendrometer useful for the present embodiment can optionally include elongated jaws connected to the transducer member for engaging the plant part. The jaws are preferably designed to cause minimum destruction and deformation of the plant tissue. The dendrometer can, for example, use single C-shaped, plastic or other noncorrodible and temperature staple transducer members. The dendrometer can alternatively include arms which can be hinged together and connected by a transducer member which experiences strain as a result of size changes of stems engaged between the hinged arms or elongated jaws attached or integral therewith. Further alternative forms of the dendrometer can utilize a pair of hinged plates which contact the plant stem or trunk. In these embodiments the transducer member extends between the pair of hinged plates and experiences measurable strain due to changes in the stem or trunk size. Other types of dendrometers are also contemplated in some embodiments of the present invention. Other types of sensing elements capable of generating signals indicative of the size of the plant part are also contemplated.

It is expected that during the life of a patent maturing from this application many relevant sensing elements will be developed and the scope of the term sensing elements is intended to include all such new technologies a priori.

The monitoring at 11 can include different plant parts at different seasons. For example, during the summer and at the end of the season, it is sufficient to measure only the trunk or stem size, whereas during the spring, both the trunk or stem size and the fruit size are preferably measured, wherein at least part of the analysis below is executed separately for the sizes of the trunk or stem, and at least part of the analysis below is executed for the size of the fruits.

At 12 the method optionally and preferably extracts, e.g., by sampling, from the signals a set {S} of temporal sequences, respectively corresponding to a set of consecutive days. Each sequence of the set describes the size of the plant part, as a function of the time, for a period of one day, wherein different sequences in {S} correspond to different days.

The ith sequence Sᵢ in set {S} includes time-ordered elements eᵢ(t₁), eᵢ(t₂) . . . , eᵢ(tₙ), where t₁, t₂ . . . , tₙ are time-instances relative to the ith day (e.g., counted from 12 AM of the previous day). Thus, the value of element eᵢ(t₁) represents the size of the plant part at time-instance t₁ during the ith day, the value of element eᵢ(t₂) represents the size of the plant part at time-instance t₂ during the ith day, and so on. Typically, the sequences in the set {S} are aligned with respect to their indices so that elements of different sequences with the same index have values that correspond to generally the same time instance but at different days. For example, when the kth element of Sᵢ corresponds to 12:00 PM of the ith day, the kth element of Sⱼ corresponds to 12:00 PM of the jth day. When there is a mismatch with respect to the number of elements in the sequences, an appropriate alignment procedure is preferably employed as known in the art. For example, elements from oversized sequences can be removed and indices of other elements can be shifted.

Instead of extracting the sequences in {S} from signals transmitted by sensing elements, they can be obtained directly (e.g., from a local or remote computer readable medium). In this case operation 11 can be skipped. These embodiments are useful for offline calculations, whereby the sequences are extracted and stored for later use.

The time-period spanned by the set {S} preferably includes a plurality of days, e.g., at least a week, or at least a month, or at least a season, or at least a year. The intervals between consecutive time-instances in each sequence are optionally and preferably sufficiently short to allow monitoring variations across different periods of the day. Typically, but not obligatorily, the elements correspond to size measurements of the plant part taken at least every 6 hours or at least every 4 hours or at least every 2 hours or at least every 1 hour or at least every 30 minutes or at least every 15 minutes.

The method continues to 13 at which morphologically equivalent pairs of sequences are identified in the set {S} of sequences. Operation 13 and also operations 14, 15, and 16, which are described below and which are based on the pairs that are identified in operation 13, are optionally and preferably executed only for the sequences that describe the size of the trunk or stem. Carbon fixation in the fruits can be estimated by establishing linear correlation of all fruit size increments to carbon fixation, and attributing all size fruit decrements to water loss.

As used herein, “a morphology of a sequence” refers to a shape of a graph obtained by plotting the values of the elements of the sequence as a function of the time, and joining the values.

As used herein, “a morphologically equivalent pair of sequences” refers to pair of sequences having morphologies that satisfy a similarity criterion.

The inventors found that morphologically equivalent pair of sequences correspond to days with similar changes in the water balance, and can therefore provide information regarding the contribution of the water balance to the changes in the size of the plant part. Such information can be used to remove this contribution from the data, allowing a more accurate estimation of the contribution of carbon fixation.

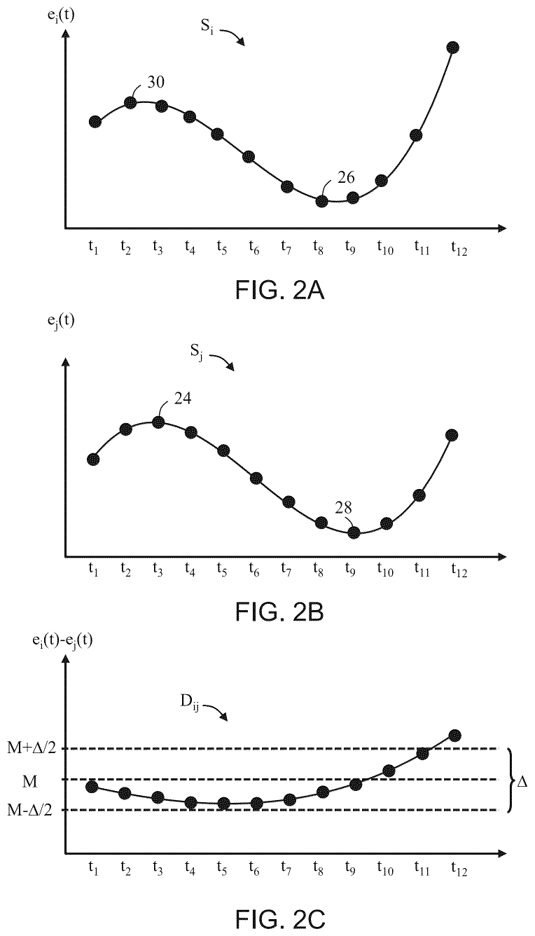

A representative example of an application of a similarity criterion between morphologies of two sequences is illustrated in FIGS. 2A-C. FIG. 2A illustrates a graph of a sequence Sᵢ which includes 12 elements eᵢ(t₁), eᵢ(t₂) . . . eᵢ(t₁₂) representing a size of the plant part at 12 different time-instances for the ith day. FIG. 2B illustrates a graph of a sequence Sⱼ which includes 12 elements eⱼ(t₁), eⱼ(t₂) . . . eⱼ(t₁₂) representing a size of the plant part at 12 different time-instances for the jth day. For example, FIGS. 2A and 2B can describe the size as measured every two hours during the ith and jth day, respectively. The sequences Sᵢ and Sⱼ are aligned as further detailed hereinabove.

FIG. 2C illustrates a distribution Dᵢⱼ of the differences eᵢ(t₁)−eⱼ(t₁), eᵢ(t₂)−eⱼ(t₂), . . . , eᵢ(t₁₂)−eⱼ(t₁₂). The dashed lines shown in FIG. 2C are a result of a statistical analysis applied to the distribution. Shown is a mean M of the distribution, and a statistical interval Δ containing the mean M. In the illustrative example which is not to be considered as limiting, the statistical interval Δ is symmetric with respect to the mean M, and so has an upper bound M+Δ/2, and a lower bound M-Δ/2. It is appreciated that non-symmetrical statistical intervals can also be employed. A representative example of a statistical interval suitable for the present embodiments is Δ=rσ, where σ is the standard deviation of the distribution Dᵢⱼ and r is a predetermined numerical parameter. Typically, r can be set to be from about 2 to about 3.

FIG. 2C illustrates one example of a test referred to herein as a “flatness test.” In this test, flatness of the distribution Dᵢⱼ is calculated and compared to a flatness test threshold p_{f}. Dᵢⱼ is defined as a distribution that passes the flatness test, when the flatness of Dᵢⱼ is above the threshold p_{f}, and as a distribution that fails to pass the flatness test otherwise. According to preferred embodiments of the present invention the morphologies of sequences Sᵢ and Sⱼ are said to satisfy the similarity criterion when the corresponding distribution of differences Dᵢⱼ passes the flatness test.

The flatness of a given distribution can optionally and preferably be defined as the portion of the distribution that is generally flat. In the flatness test that is illustrated in FIG. 2C, the generally flat portion of Dᵢⱼ is defined as the collection of all elements of Dᵢⱼ is that are within the statistical interval 4. Other ways to search for the generally flat portion are also contemplated. For example, the collection of all elements of the distribution at which the absolute value of the slope of the distribution is less than a predetermined threshold can be defined as belonging to the generally flat portion. The slope can be found by calculating the first derivative of the distribution with respect to the time.

When the flatness is defined as the portion of the distribution that is generally flat, the flatness test threshold pr can be defined as percentage. In this case, the distribution passes the flatness test when the generally flat portion includes more than pr % of the elements of the distribution (e.g., when more than pr % of the elements of the distribution are within the statistical interval 4). A typical value for the threshold pr is from about 60% to about 95% or from about 75% to about 85%. Since the elements of each sequence span over 24 hours, the selection p_{f}=60% corresponds to about 14.4 hours and the selection p_{f}=95% corresponds to about 22.8 hours. In some embodiments of the present invention the morphologies of sequences Sᵢ and Sⱼ are said to satisfy the similarity criterion when the generally flat portion of the corresponding distribution Dᵢⱼ includes elements that collectively span over at least 18 hours or at least 19 hours or at least 20 hours.

Notice that the collective span need not be continuous. For example, suppose that Dᵢⱼ includes 12 elements corresponding to size measurements taken every two hours. Suppose further that the generally flat portion includes 10 of these elements (corresponding to a collective span of 20 hours). These 10 elements need not be consecutive within Dᵢⱼ. Specifically, Dᵢⱼ passes the test both in the case in which the flat portion includes elements e(t₁) through e(t₁₀), and in the in which the flat portion includes all elements except, e.g., elements e(t₅) and e(t₉).

Operation 13 is preferably executed under the condition that the set {S} is searched for morphologically equivalent pairs that correspond to days that are sufficiently close to each other. Thus, instead of applying the similarity criterion to all possible pairs in set {S}, only sequences of days that are within a predetermined interval from each other are tested. In the above notation, the similarity criterion is applied to sequences Sᵢ and Sⱼ is and only if the ith day and the jth day are within the predetermined interval from each other. The predetermined interval is preferably less than four days, and more preferably less than three days. In various exemplary embodiments of the invention the similarity criterion is applied to pairs of sequences when the sequences in the pair correspond to adjacent days. For example, when the set {S} is by itself a sequence S₁, S₂ . . . . S_{N}, then the similarity criterion is applied to the pair Sᵢ and Sⱼ when |j−i|=1. These embodiments are advantageous both from the standpoint of simplicity (less pairs to consider) and from the standpoint of the water balance mechanism, wherein equivalent morphologies among adjacent days is likely to indicate that the water balance was the same in these days.

At 14 a parameter representing each of at least some of the sequences is optionally and preferably selected. The selected parameter can be any parameter that represents the respective sequence. Preferably, the parameter is a value of the element at a local maximum of the sequence. When there is more than one local maximum, the parameter is preferably the value of the element at the local maximum that is immediately before the first local minimum of the sequence. In the representative illustrations of FIGS. 2A and 2B, the elements at local maxima are shown at 30 and 24, respectively, and the elements at the first local minima are shown at 26 and 28, respectively. Use of the local maximum as the parameter is advantageous because at the local maximum the water potential is minimal or practically zero, and so represent more accurately net changes in dry matter. Yet, since, as will be described below, the parameters of the pairs are eventually subtracted, the present embodiments also contemplate using other features, such as, but not limited to, the mean of the sequence, or any other element of the sequence as the parameters that represent the sequences.

The method optionally and preferably proceeds to 15 at which a smoothing operation is applied to the selected parameters. In these embodiments a sequence is constructed from all the selected parameters, where the ordering of the sequence is based on the orders of the days with which the selected parameters are associated, and the smoothing operation is applied to the constructed sequence. The smoothing can comprise a moving average, more preferably a weighted moving average. Representative examples of weighted moving averages suitable for the present embodiments include, without limitation, a simple weighted moving average, an exponential weighted moving average, a triangular weighted moving average, a Gaussian weighted moving average, and a double exponential weighted moving average. In experiments performed by the inventers, the smoothing included an exponential weighted moving average with a half-life of 4 days.

Once a morphologically equivalent pair of sequences is identified in {S}, the method continues to 16 at which the selected parameters that represent the sequences of the pair are subtracted from each other. Operation 16 is preferably repeated for at least a portion of the identified pairs, and more preferably for all the identified pairs. Since days with similar morphologies have similar water balance variations, the subtraction cancels the contribution of the water balance to the changes in the size of the plant part, providing an estimate to the change in the size due to a change in the dry matter and carbon storage. In embodiments in which the smoothing 15 is executed, the subtraction is between the smoothed version of the parameters.

The method continues to 17 at which the amount of carbon fixation in the plant is estimated based on the estimate size change. This can be done by employing a model that relates the weight of the plant part to the weight of the whole plant, excluding the weight of the fruits, and thereafter employing a model that relates the weight of the whole plant to its biomass. When the sequences include separate information for the trunk size and for the fruit size (for example, during spring), the amount of carbon fixation in wood tissue is estimated separately from the amount of carbon fixation in fruit tissue, and these estimated amounts are thereafter added to each other. For the estimation of the amount of carbon fixation in fruit tissue, it is not necessary to estimate the weight of the whole plant, but rather the overall weight of the fruits.

Models for estimating the weight of the whole plant based on the size of the trunk or stem are known, and typically take into account factors like the species of the plant, the age of the plant, the region of growth, and the pruning method. Representative examples of such models suitable for the present embodiments are found in Wu T. Wang Y. Yu C, Chiarawipa R, Zhang X, Han Z, et al. (2012) Carbon Sequestration by Fruit Trees-Chinese Apple Orchards as an Example. PLOS ONE 7(6): e38883, and in Fernández-Puratich, H., Oliver-Villanueva, J. V., Alfonso-Solar, D., and Peñalvo-López, E. (2013) Quantification of potential lignocellulosic biomass in fruit trees grown in Mediterranean regions BioRes. 8(1), 88-103, the contents of which are hereby incorporated by reference.

Models for estimating the biomass based on the weight of the whole plant are also known and typically provide an estimate under certain assumptions regarding the weight percent carbon in the dry matter, and the water content. Representative examples of such models suitable for the present embodiments are found in Dias, Daniela Pereira, and Ricardo Antonio Marenco “Tree growth, wood and bark water content of 28 Amazonian tree species in response to variations in rainfall and wood density” Volume 9, Número JUNE 2016, Pags. 445-451 (2016), in Lamani, Shrinivas, et al. “Analysis of Free Sugars, Organic Acids, and Fatty Acids of Wood Apple (Limonia acidissima L.) Fruit Pulp” Horticulturae 8.1 (2022): 67, in Campeanu, Gheorghe, Gabriela Neata, and Gina Darjanschi. “Chemical composition of the fruits of several apple cultivars growth as biological crop.” Notulae Botanicae Horti Agrobotanici Cluj-Napoca 37.2 (2009): 161-164, and in Marini, R. P., Schupp, J. R., Baugher, T. A., & Crassweller, R. (2019). Relationships between Fruit Weight and Diameter at 60 Days after Bloom and at Harvest for Three Apple Cultivars, HortScience horts, 54(1), 86-91. Typical models estimate about 50 wt. % carbon in the dry matter, about 60-80 wt. % water in fruits, and about 50 wt. % water in woody tissue.

The estimate 17 can be on a daily basis, in which case it is based only on the data (size, size change, age, etc.). Alternatively, the estimation of the amount of carbon fixated is over a period of a plurality of days (e.g., at least 10, or at least 20, or at least 30, or at least 90, or at least 180, or at least 360 days or more) based on the accumulated of size changes over these days. In some embodiments of the present invention the method proceeds to 18 at which daily size changes for sequences in {S} that fail to be identified as morphologically equivalent are interpolated, based on the size changes for the morphologically equivalent sequences. In some embodiments of the present invention the method proceeds to 19 at which forward extrapolation is applied to the accumulated size changes over a future time period. Forward extrapolation is useful for predicting the expected amount of carbon fixation in a future time period. The length of future time period is preferably less than six months or less than six five months or less than four months or less than three months.

The estimated carbon fixation obtained at 17, and optionally and preferably also the interpolated carbon fixation obtained at 18 and/or the predicted carbon fixation obtained at 19 can be used as a basis to for an estimation 20 of the carbon fixation in a population of plants such as, but not limited to, a block of trees, an orchard, a field of the like. The population preferably includes two or more plants grown at the same geographical region as the monitored plant. This can be done by applying statistical techniques. In the simplest case, the estimate for a single plant is multiplied by the number of plants in the population. Also contemplated, are embodiments in which the sensor(s) is/are attached to more than one plants in the population, and the method is executed for each of the monitored plant. The average carbon fixation per monitored plant can be calculated and then multiplied by the number of plants in the population to obtain an estimate per population. Further contemplated are embodiments in which the plant size distribution within the population is obtained from an external source (e.g., a computer readable medium) and utilized for estimating estimate the amount of carbon fixation per population, by calculating a weighted sum of carbon fixation over the population, where the weights of the sum are extracted from the plant size distribution.

Some embodiments of the present invention relate to crop management based on the estimated carbon fixation. The crop management can include execution of one or more operations, such as, but not limited to, scheduled irrigation, fertilization, temperature control, humidity control and the like. It was found by the present inventors that the carbon fixation can be increased by applying crop management operations directed to increase the amount of dry matter in the crop. Thus, according to some embodiments of the present invention the method proceeds to 21 at which a crop treatment system is operated responsively to the estimated amount. In various exemplary embodiments of the invention the treatment system is operated to increase the carbon fixation of the plant population. For example, the treatment system can be operated to ensure that the amount of carbon fixation of the plant population is higher than the predicted amount, and/or higher than amount calculated in previous seasons or years. Preferably, the operation of the treatment system and the estimation of carbon fixation is executed repeatedly, wherein at each repetition the estimated carbon fixation is compared to a baseline, and the crop treatment system is operated responsively to the comparison. In some embodiments, at least one operational parameter of a crop treatment system is varied when the estimated carbon fixation is below the baseline, in some embodiments at least one operational parameter of the crop treatment system is varied when a difference between the estimated carbon fixation and the baseline is below a predetermined threshold.

The present embodiments also contemplate calculating a predicted yield of a crop based on the received sequences. This can be done using any procedure known in the art. Representative examples of such calculations are found in U.S. Pat. No. 10,721,880, the contents of which are hereby incorporated by reference. In some embodiments of the present invention the crop treatment system is operated to increase the estimated carbon fixation even though such operation reduces or does not increase the predicted yield.

Some embodiment of the present invention contemplate trading the carbon fixation in an emission allowance trading system that facilitate trade of emission allowances and offsets among participants. In such a system the estimated carbon fixation can be used to obtain credits awarded to attributed to environmental benefactors. Thus, in some embodiments of the present invention the method proceeds to 22 at which a connection to a user account within an emission allowance trading system is established, and a database record pertaining to the estimated amount is associated with the user account.

The method ends at 23.

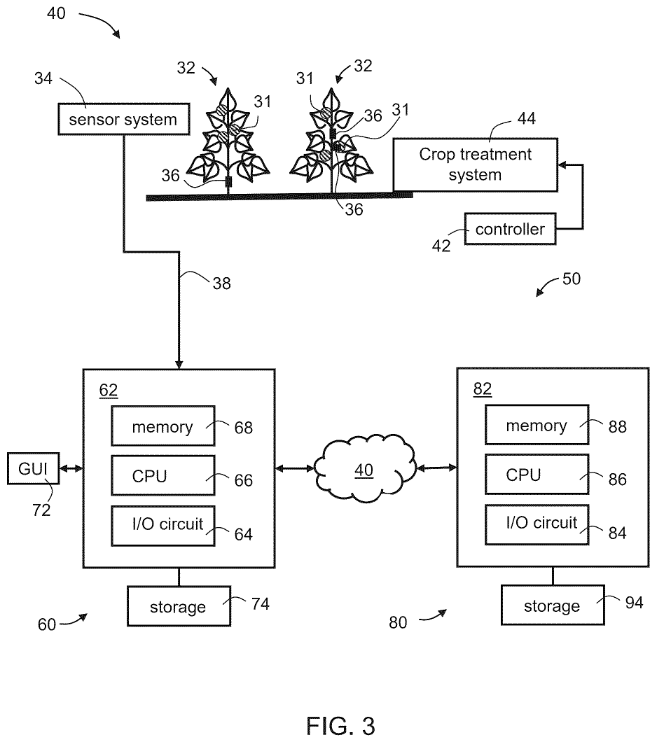

FIG. 3 is a schematic illustration showing a block diagram of a system 40 for estimating amount of carbon fixation in one or more plants 32, according to some embodiments of the present invention, and optionally and preferably also for controlling fruit quality.

System 40 comprises a sensor system deployed and configured for measuring and transmitting signals describing the size of a part of plant 32. Sensor system is designated by block 34, but represents also embodiments in which the sensor system includes a plurality of sensing elements arranged for measuring the growth for each of at least a portion of the plants 32. Representative examples of such sensing elements are shown at 36. The sensing elements are optionally and preferably attached to a part of plant, preferably to the truck of the plant, as illustrated in FIG. 3, but may also be attached to other parts, as further detailed hereinabove. In various exemplary embodiments of the invention the sensor system comprises at least one dendrometer. In some embodiments of the present invention the sensor system comprises both sensing elements 36 that measure the size of the stem and sensing elements 36 that measure the size of the fruits 31.

Sensor system 34 can transmit the measured data over a dedicated communication channel 38 which can be a wired communication channel or a wireless communication channel as desired. Alternatively, system 34 can transmit the measured data over a communication network 46, such as a local area network (LAN), a wide area network (WAN) or the Internet.

System 40 optionally and preferably comprises a computing platform 50 which is configured to receive the signals from the sensor system, and execute at least some of the operations described above with respect to method 10. Optionally, system 40 also comprises a controller 42 which communicates with computing platform 50 (over the dedicated communication channel 38 or the communication network 46) and is configured for operating a crop treatment system 44 responsively to instructions transmitted by computing platform 50 as further detailed hereinabove. In some embodiments of the present invention system 40 also comprises the crop treatment system 44.

Shown in FIG. 3 is a computing platform that includes a client-server configuration having a client computer 60 and a server computer 80. However, this need not necessarily be the case, since, for some applications, it may not be necessary for system 40 to include a client-server configuration. For example, system 40 can include only one of the computers.

Client computer 60 has a hardware processor 62, which typically comprises an input/output (I/O) circuit 64, a hardware central processing unit (CPU) 66 (e.g., a hardware microprocessor), and a hardware memory 68 which typically includes both volatile memory and non-volatile memory. CPU 66 is in communication with I/O circuit 64 and memory 68. Client computer 60 preferably comprises a user interface, e.g., a graphical user interface (GUI), 72 in communication with processor 62. I/O circuit 64 preferably communicates information in appropriately structured form to and from GUI 72.

Server computer 80 can similarly include a hardware processor 52, an I/O circuit 84, a hardware CPU 86, and a hardware memory 88. I/O circuits 64 and 84 of client 60 and server 80 computers preferable operate as transceivers that communicate information with each other via a wired or wireless communication. For example, client 60 and server 80 computers can communicate via network 46. Server computer 80 can be in some embodiments be a part of a cloud computing resource of a cloud computing facility in communication with client computer 60 over the network 46.

GUI 72 and processor 62 can be integrated together within the same housing or they can be separate units communicating with each other. GUI 72 can optionally and preferably be part of a system including a dedicated CPU and I/O circuits (not shown) to allow GUI 72 to communicate with processor 62. Processor 62 issues to GUI 72 graphical and textual output generated by CPU 66. Processor 62 also receives from GUI 72 signals pertaining to control commands generated by GUI 72 in response to user input. GUI 72 can be of any type known in the art, such as, but not limited to, a keyboard and a display, a touch screen, and the like. In preferred embodiments, GUI 72 is a GUI of a mobile device such as a smartphone, a tablet, a smartwatch and the like. When GUI 72 is a GUI of a mobile device, the CPU circuit of the mobile device can serve as processor 62 and can execute the method of the present embodiments by executing code instructions.

Client 60 and server 80 computers can further comprise one or more computer-readable storage media 74, 94, respectively. Media 74 and 94 are preferably non-transitory storage media storing computer code instructions for executing the method of the present embodiments, and processors 62 and 82 execute these code instructions. The code instructions can be run by loading the respective code instructions into the respective execution memories 68 and 88 of the respective processors 62 and 82.

In operation, the sensor system that is deployed in the field transmits to processor 62 of client computer 60 signals pertaining to the size of the plant part. Processor 62 preferably transmits the monitored size to server computer 80 over network 46. Typically, processor 62 samples the signals to provide the set {S} of sequences, and transmits the set {S} to server computer 80. Alternatively, processor 62 transmits the signals received from the sensor system to server computer 80 in which case the sampling is executed at server computer 80 to generate the set {S} of sequences.

Media 94 can store computer code instructions for estimating carbon fixation as further detailed hereinabove, and for generating output containing the estimated carbon fixation. The output can be transmitted to client computer 60 for displaying on GUI 72. The computer code instructions can optionally also cause computer 80 to generate instruction signals for operating crop treatment system 44 responsively to the estimated carbon fixation. The instruction signals can be transmitted directly to controller 42 or to client computer 60 for transmitting them to controller 42.

When computing platform includes a single computer, the above operations are all executed by the same computer. In these embodiments, the same computer that receives the signals from the sensor system also estimates the carbon fixation and optionally generates the instruction signals. For example, system 40 can includes only computer 60, in which case the computer code instructions can be stored in media 74.

As used herein the term “about” refers to ±10%.

The terms “comprises”, “comprising”, “includes”, “including”, “having” and their conjugates mean “including but not limited to”.

The term “consisting of” means “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise. For example, the term “a compound” or “at least one compound” may include a plurality of compounds, including mixtures thereof.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Various embodiments and aspects of the present invention as delineated hereinabove and as claimed in the claims section below find experimental support in the following examples.

### EXAMPLES

Reference is now made to the following examples, which together with the above descriptions illustrate some embodiments of the invention in a non limiting fashion.

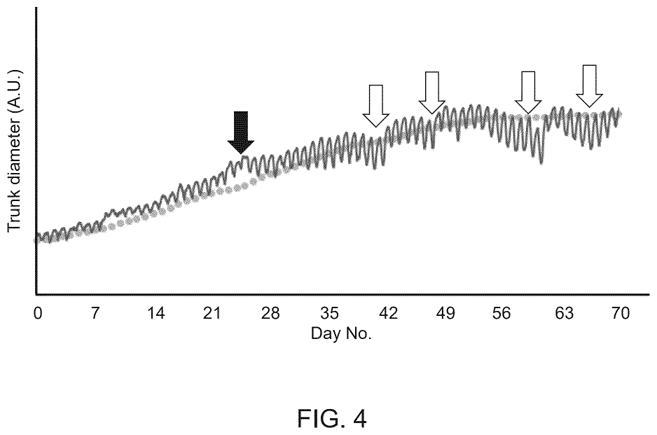

FIG. 4 is a plotted version of a set of 70 sequences corresponding to a set of 70 consecutive days. The set is shown as a solid line. The sequences are not shown individually but are concatenated on the plot. The sequences were extracted from signals received from one dendrometer by sampling the signals at a sampling rate of one sample per hour. The dendrometer was attached to the trunk and provided signals indicative of trunk diameter. Also shown, as dots, are the estimated size changes as calculated according to some embodiments of the present invention. The subtracted parameter was the value of the element at the local maximum that is immediately before the first local minimum of the respective sequence, and the results shown were obtained after smoothing using an exponential weighted moving average with a half-life of 4 days.

Over this 70 day period, five events changed the water content in the trunk. One rain event (marked by a black arrow) and four water stress events (marked by white arrows). The net growth rate of the trunk was not changed due to the temporal changes in water content. However, the four water stress events, which were a result of insufficient irrigation frequency, did cause a reduction in net-growth rate. This demonstrates that a rain event apparently changes the trunk size without effecting the net-growth while a long lasting stress compromise photosynthesis and rescue the net-growth. Absent the procedure of the present embodiments, these events would be wrongly interpreted in terms of carbon fixation.

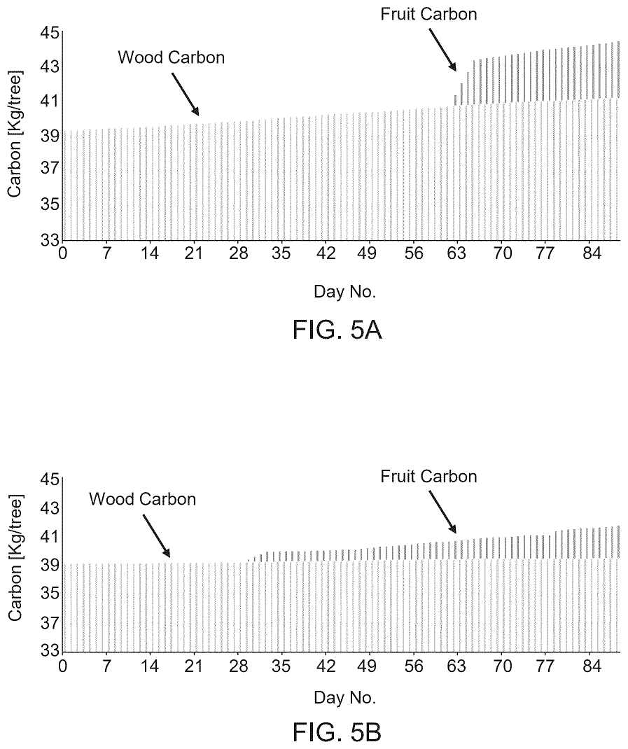

FIGS. 5A and 5B show calculated daily change in carbon content of two gala apple irrigation projects (3 trees each, ages 13-16 years) located in Washington. FIG. 5A shows result of a high vigor project and FIG. 5B shows results of a low vigor project. The calculation considers an initial trunk diameter of 23 cm and a fruit load of 100 fruits per tree. The daily estimated diameter change of the trunk was calculated for each tree as described above. The woody organs was calculated from the and the daily estimated diameter change of the trunk using a relationship between trunk diameter to the rest of the apple tree organs described in Wu et al. supra. The biomass accumulation in fruits were calculated from daily fruit size measurements and the correlation between gala fruit diameter to weight found in Marini et al supra, multiply by the number of fruits on the tree.

Considering the water content in each tissue type (50% and 80% in wood or fruit, respectively) the amount of carbon stored in these trees ranged from about 42 Kg to about 44 Kg per tree. The planting density of gala apples in Washington at these ages is about 872 trees per acre. Thus, gain in carbon weight in these two projects translates to about 1.7 ton carbon per acre.

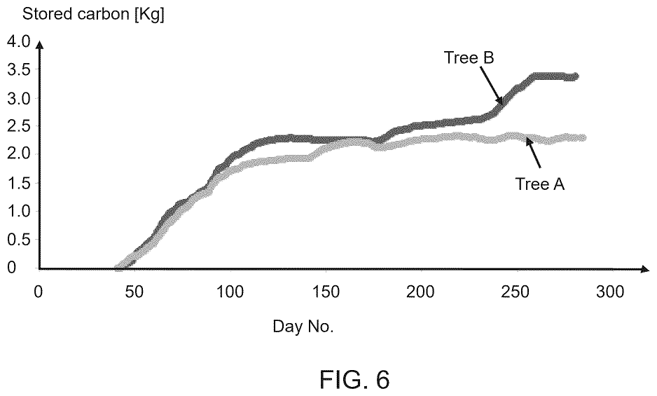

FIG. 6 shows estimated carbon stored in two almond trees during an irrigation trial in Lavi Israel. The results for the two trees are marked on FIG. 6 as “tree A” and “tree B”. As in the case of the apples, above, differences in tree productivity and wellbeing translates to different rates of carbon storage. The estimation was based on a relationship between trunk diameter and tree mass that was constructed using structural and dimensional analysis preformed on sixty 3 years old almond trees taken from lysimeter experiment in Gilat Israel.

The two trees shown in FIG. 6 received a significantly deferent water amount over the season.

Tree A received an annual amount of 620 mm resulting in a constant water stress from June (about day 110) to August (about day 180), including a reduction in photosynthesis, stomata conductivity and steam water potential. Under these conditions, the carbon gained by the tree was 2.3 Kg, equivalent to or 270 Kg carbon per acre.

Tree B was irrigated over 900 mm during this season. The higher irrigation amount kept the tree under at high productivity performance for most of the season. Higher rates of carbon accumulation can be observed during June (days 110-140) due to fruit maturation, and during August-September (day 170-200) due to post harvest. The higher carbon accumulation rates of tree B during June which are a result of more adequate irrigation amounts resulted in significantly larger kernel (nuts) over 12% heavier compared to those of tree A.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

It is the intent of the applicant(s) that all publications, patents and patent applications referred to in this specification are to be incorporated in their entirety by reference into the specification, as if each individual publication, patent or patent application was specifically and individually noted when referenced that it is to be incorporated herein by reference. In addition, citation or identification of any reference in this application shall not be construed as an admission that such reference is available as prior art to the present invention. To the extent that section headings are used, they should not be construed as necessarily limiting. In addition, any priority document(s) of this application is/are hereby incorporated herein by reference in its/their entirety.

1. A method of estimating amount of carbon fixation in a plant, the method comprising:
receiving a set of temporal sequences, respectively corresponding to a set of consecutive days, each sequence describing a size of a part of the plant as measured repeatedly over one of the days;
identifying morphologically equivalent pairs of sequences in said set of sequences;
subtracting between parameters representing sequences in each pair of at least a portion of said pairs, to provide a size change of the plant part for said pair; and
estimating the amount of carbon fixation in the plant based on said size change.

2. The method according to claim 1, wherein said identifying comprises applying a statistical analysis to a distribution of differences between values of respective elements of said sequences of said pair.

3. The method according to claim 1, wherein said statistical analysis comprises a flatness test.

4. (canceled)

5. The method according to claim 1, wherein said pair corresponds to two adjacent days of said set of consecutive days.

6. (canceled)

7. The method according to claim 1, wherein said parameters comprise a local maximum of each of said sequences in said pair.

8. (canceled)

9. The method according to claim 1, comprising applying smoothing to said parameters prior to said subtraction.

10. (canceled)

11. The method according to claim 9, wherein said smoothing comprises a moving average.

12-14. (canceled)

15. The method according to claim 1, wherein said estimating comprising estimating a daily amount.

16. (canceled)

17. The method according to claim 1, wherein said estimating comprising estimating an amount of carbon fixated over a period of a plurality of days based on accumulation of size changes over said plurality of days.

18. (canceled)

19. The method according to claim 17, comprising interpolating daily size changes for sequences that fail to be identified as morphologically equivalent.

20. (canceled)

21. The method according to claim 17, comprising applying forward extrapolation to said accumulated size changes over a future time period, and predicting an expected amount of carbon fixation in said future time period.

22-24. (canceled)

25. The method according to claim 1, comprising estimating a weight of said plant based on said size, wherein said estimating is based also on said estimated weight.

26. (canceled)

27. The method according to claim 1, wherein said plant part is selected from the group consisting of a trunk, a stem, and a fruit.

28. (canceled)

29. (canceled)

30. The method according to claim 1, comprising receiving signals from a sensing element attached to said plant part, and extracting said temporal sequences from said signal.

31. (canceled)

32. The method according to claim 30, wherein said sensing element comprises a dendrometer.

33. (canceled)

34. The method according to claim 1, comprising applying a statistical procedure to the amount of carbon fixation in the plant to provide an estimate for an amount of carbon fixation in a population of plants.

35. (canceled)

36. The method according to claim 1, comprising establishing a connection to a user account within an emission allowance trading system, and associating a database record pertaining to said estimated amount to said user account.

37. (canceled)

38. The method according to claim 1, comprising operating a crop treatment system responsively to said estimated amount.

39. (canceled)

40. A computer software product, comprising a non-volatile computer-readable medium in which program instructions are stored, which instructions, when read by a data processor, cause the data processor to receive a set of temporal sequences, respectively corresponding to a set of consecutive days, each sequence describing a size of a part of the plant as measured repeatedly over one of the days, and to execute the method according to claim 1.

41. (canceled)

42. A system for estimating amount of carbon fixation in a plant, the system comprising:
a communication system configured to receive over a communication network a set of temporal sequences, respectively corresponding to a set of consecutive days, each sequence describing a size of a part of the plant as measured repeatedly over one of the days; and
a data processor configured to receive said signal and to execute the method according to claim 1.

43. (canceled)
